(19) United States
(12) Patent Application Publication
(10) Pub. No.: US 2025/0298298 A1
(43) Pub. Date: Sep. 25, 2025

(54) LIGHT SOURCE DEVICE AND PROJECTION DEVICE

(71) Applicant: Coretronic Corporation, Hsin-Chu (TW)

(72) Inventor: Wen-Ching HO, Hsin-Chu (TW)

(21) Appl. No.: 18/610,283

(22) Filed: Mar. 20, 2024

(51) Int. Cl. G03B 21/16; G03B 21/20; H05K 1/02

(52) U.S. Cl. CPC G03B 21/16; G03B 21/2013; G03B 21/2033; H05K 1/0201; H05K 2201/066; H05K 2201/10121

(57) ABSTRACT

A light source device includes a heat dissipation base, a circuit board, a light source unit, a mask cover, a plurality of pressing members, and a plurality of first fasteners. The circuit board is disposed on the heat dissipation base. The light source unit, which is electrically connected to the circuit board, is disposed on the heat dissipation base and located in a through hole of the circuit board. The plurality of pressing members is fixed on the mask cover. The plurality of first fasteners passes through the mask cover, the plurality of circuit board, and the heat dissipation base in sequence, to fasten the mask cover and the circuit board on the heat dissipation base, and the mask cover is connected to the light source unit on the heat dissipation base through the plurality of pressing members.

### TECHNICAL FIELD

The disclosure relates to a light source device and a projection device, and in particular to a light source device with a relatively good heat dissipation effect and a projection device using the light source device.

### DESCRIPTION OF RELATED ART

With the advancement of projection technology, users' requirements for a high-brightness projection device are getting higher. The higher the brightness of the light source device of the projection device is, the more heat the light source device generates. Since a large amount of heat energy may seriously affect the efficiency and reliability of the projection device, heat dissipation is an extremely important issue for the projection device.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY OF THE INVENTION

The disclosure provides a light source device with a relatively good heat dissipation effect and a projection device using the light source device.

Other objectives and advantages of the disclosure will be further understood from the technical features disclosed herein.

An embodiment of the disclosure provides a light source device. The light source device includes a heat dissipation base, a circuit board, a light source unit, a mask cover, a plurality of pressing members, and a plurality of first fasteners. The heat dissipation base is provided with a plurality of first fastener holes. The circuit board is provided with a through hole and a plurality of second fastener holes, and is disposed on the heat dissipation base. The light source unit is electrically connected to the circuit board, and is disposed on the heat dissipation base and located in the through hole. The mask cover is provided with a plurality of third fastener holes, and the plurality of pressing members are fixed on the mask cover. The plurality of first fasteners passes through the plurality of third fastener holes, the plurality of second fastener holes, and the plurality of first fastener holes in sequence, the plurality of first fasteners is configured to fasten the mask cover and the circuit board on the heat dissipation base, and the mask cover is connected to the light source unit on the heat dissipation base through the plurality of pressing members.

An embodiment of the disclosure provides a projection device. The projection device includes the light source device, a light valve, and a projection lens. The light valve is disposed on a transmission path of an illumination beam generated by the light source device, and is configured to convert the illumination beam into an image beam. The projection lens is disposed on a transmission path of the image beam, and is configured to project the image beam.

Based on the above, in the embodiments of the light source device or the projection device of the disclosure, the plurality of first fasteners fastens the mask cover and the circuit board on the heat dissipation base simultaneously, and the mask cover is connected to the light source unit on the heat dissipation base through the plurality of pressing members. Since the light source unit, which is the main heat source of the projection device, is fixed on the heat dissipation base in a pressing manner rather than a fastening manner with the first fasteners, the heat dissipation base has more areas on the opposite surface where the light source unit is disposed, which are configured for heat dissipation and avoid the locations of the first fasteners, thereby improving the heat dissipation effect.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of a projection device according to an embodiment of the disclosure.

FIG. 2A is a schematic diagram of the light source device of the projection device of FIG. 1 from a first viewing angle according to an embodiment of the disclosure.

FIG. 2B is an exploded diagram of the light source device of FIG. 2A.

FIG. 3A is a schematic diagram of the light source device of the projection device of FIG. 1 from a second viewing angle according to an embodiment of the disclosure.

FIG. 3B is an exploded diagram of the light source device of FIG. 3A.

FIG. 4 is an assembly diagram showing part of the light source device of FIG. 2B.

FIG. 5 is a diagram showing a top view of part of the light source unit of FIG. 2B.

FIG. 6A is a schematic diagram of the light source device of the projection device of FIG. 1 from a third viewing angle according to an embodiment of the disclosure.

FIG. 6B is a cross-sectional view along a line segment AA′ in FIG. 6A.

FIG. 7 is a schematic diagram of the mask cover and the pressing members of FIG. 3B.

FIG. 8 is an enlarged schematic diagram of a region C in FIG. 3A.

### DETAILED DESCRIPTION

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

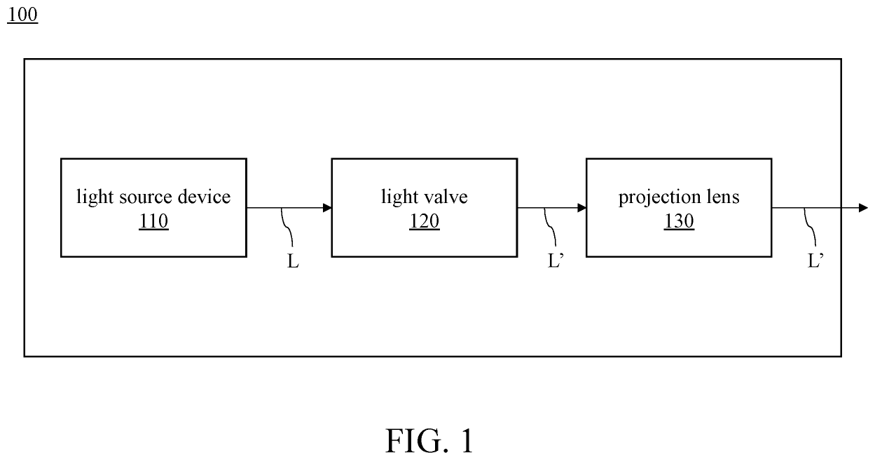

FIG. 1 is a schematic view of a projection device according to an embodiment of the disclosure. With reference to FIG. 1, in this embodiment, a projection device 100 comprises a light source device 110, a light valve 120 and a projection lens 130. The projection device 100 may be a projector. The light source device 110 is configured to generate an illuminating beam L. The light valve 120 is disposed on a transmission path of the illuminating beam L, and is configured to convert the illuminating beam L into an image beam L′. The projection lens 130 is disposed on a transmission path of the image beam L′, and is configured to project the image beam L′ outside the projection device 100. In an embodiment, the light source device 110 is configured to emit red light, green light and blue light, and the illuminating beam L comprises at least one of the red light, the green light and the blue light. In another embodiment, the projection device 100 may further comprises a phosphor wheel. Through the phosphor wheel, a wavelength of the light emitted by the light source device 110 may change, to form different colors of the illuminating beam L.

In this embodiment, the light valve 120 may be a reflective light modulator, such as a liquid crystal on silicon panel (LCoS panel) and a digital micro-mirror device (DMD), but embodiments of the present disclosure are not limited thereto. In some embodiments, the light valve 120 may also be a transmissive light modulator, such as a transparent liquid crystal panel, an electro-optical modulator, a magneto-optic modulator, and an acousto-optic modulator (AOM). The projection lens 130 may comprise a combination of one or more optical lenses with diopter values, such as biconcave lenses, biconvex lenses, concave-convex lenses, convex-concave lenses, plane-convex lenses, and plane-concave lenses.

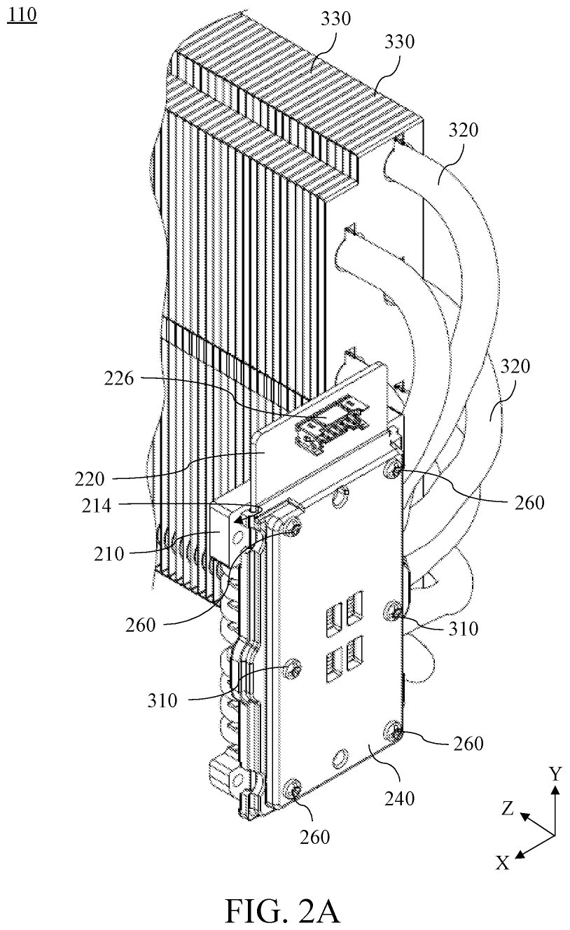

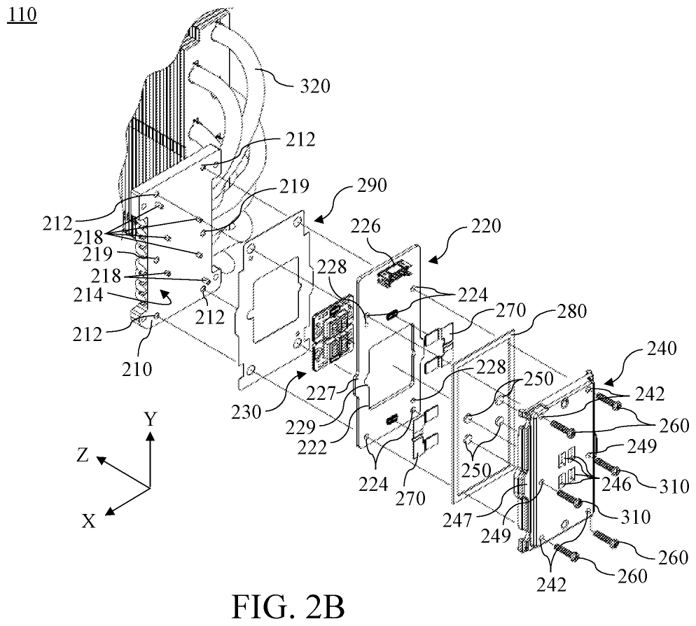

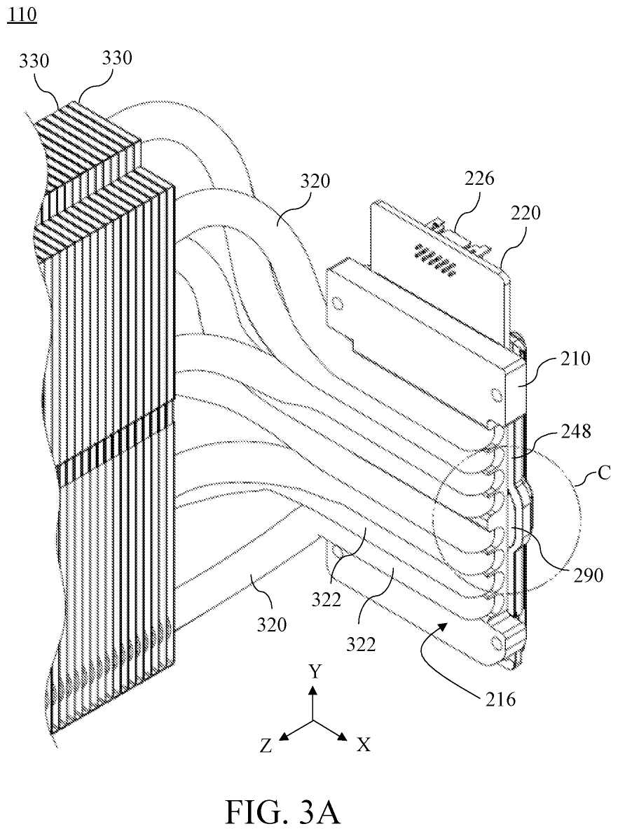

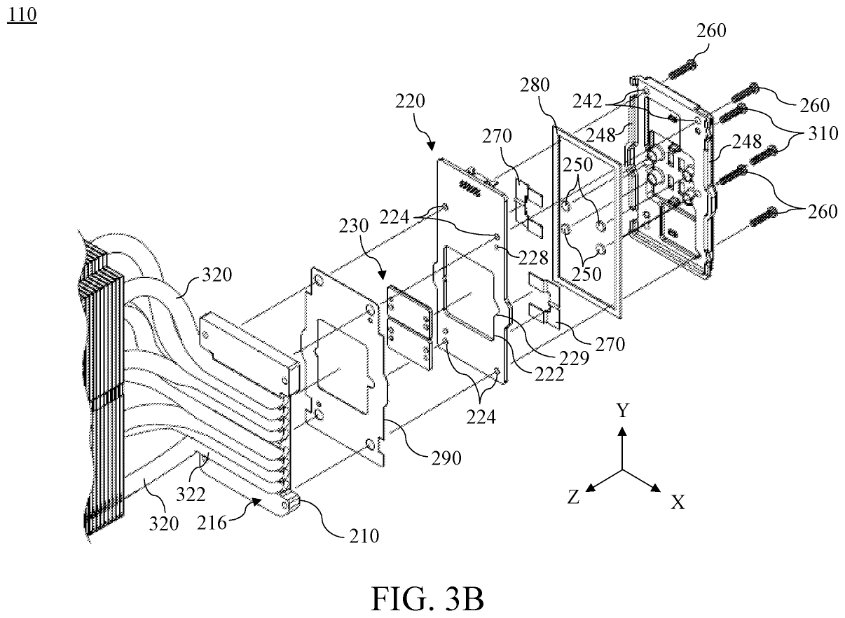

FIG. 2A is a schematic diagram of the light source device of the projection device of FIG. 1 from a first viewing angle according to an embodiment of the disclosure. FIG. 2B is an exploded diagram of the light source device of FIG. 2A. FIG. 3A is a schematic diagram of the light source device of the projection device of FIG. 1 from a second viewing angle according to an embodiment of the disclosure. FIG. 3B is an exploded diagram of the light source device of FIG. 3A. Referring to FIGS. 2A, 2B, 3A and 3B together, the light source device 110 comprises a heat dissipation base 210, a circuit board 220, a light source unit 230, a mask cover 240, a plurality of pressing members 250, and a plurality of first fasteners 260.

The heat dissipation base 210 is provided with a plurality of first fastener holes 212, and comprises a first surface 214 and a second surface 216 opposite to each other. The heat dissipation base 210 is made of, for example, a metal material containing aluminum, copper or an alloy containing at least one of these. The first fastener holes 212 are disposed as close to the periphery of the heat dissipation base 210. For example, the four first fastener holes 212 are disposed on the four corners of the heat dissipation base 210.

The circuit board 220 is provided with a through hole 222 and a plurality of second fastener holes 224, and is disposed on the first surface 214 of the heat dissipation base 210. The plurality of second fastener holes 224 surround the through hole 222. The circuit board 220 is, for example, a printed circuit board or a flexible printed circuit.

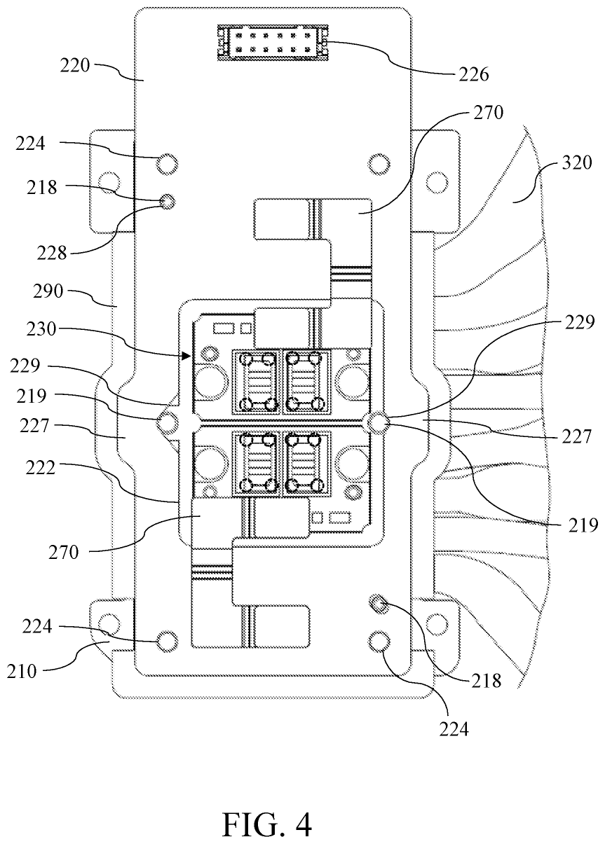

FIG. 4 is an assembly diagram showing part of the light source device of FIG. 2B. Referring to FIGS. 2A, 2B and 4 together, the light source unit 230 is electrically connected to the circuit board 220, and is disposed on the first surface 214 of the heat dissipation base 210 and located in the through hole 222. There is a gap between the light source unit 230 and the circuit board 220, that is, the light source unit 230 does not connect to the circuit board 220 physically, and the light source unit 230 is electrically connected to the circuit board 220 by the wire(s) 270 such as the flat cable(s).

The circuit board 220 of this embodiment is further provided with a connector 226. The connector 226 is configured to receive power and/or a driving signal through a wire, and the circuit board 220 transmits the power and/or the driving signal to the light source unit 230 through the wire(s) 270, so that the light source unit 230 emits light.

The mask cover 240 is provided with a plurality of third fastener holes 242, and the plurality of pressing members 250 are fixed on the mask cover 240, wherein the mask cover 240 is made of, for example, a metal material. The plurality of pressing members 250 are located between the plurality of third fastener holes 242.

The plurality of first fasteners 260 pass through the plurality of third fastener holes 242 of the mask cover 240, the plurality of second fastener holes 224 of the circuit board 220, and the plurality of first fastener holes 212 of the heat dissipation base 210 in sequence, to fasten the mask cover 240 and the circuit board 220 on the heat dissipation base 210, and the mask cover 240 is connected to the light source unit 230 on the heat dissipation base 210 through the plurality of pressing members 250. The mask cover 240 may press the light source unit 230 through the plurality of pressing members 250, so that the light source unit 230 is fixed on the heat dissipation base 210. The plurality of first fasteners 260 comprises, for example, a plurality of screws and/or a plurality of bolts.

In other words, the heat dissipation base 210 is only provided with the plurality of first fastener holes 212 for fastening the mask cover 240 and the circuit board 220 on the heat dissipation base 210 simultaneously, and the light source unit 230 is pressed against the heat dissipation base 210 by the plurality of pressing members 250 when the mask cover 240 is fastened on the heat dissipation base 210. Compared with the need to provide different fastener holes on the heat dissipation base for fastening the circuit board and the light source unit, the design of the light source device 110 may effectively reduce the processing cost on the heat dissipation base 210, reduce the number of first fastener holes 212 to reduce the use cost, and make the heat dissipation base 210 have more areas on the second surface 216, which are configured for heat dissipation and avoid the locations of the first fasteners 260, thereby improving the heat dissipation effect.

In this embodiment, the first fastener holes 212 of the heat dissipation base 210, the second fastener holes 224 of the circuit board 220, and the third fastener holes 242 of the mask cover 240 correspond to each other in positions; a number of the first fastener holes 212, the second fastener holes 224, the third fastener holes 242, and the first fasteners 260 is four, and the four first fasteners 260 pass through the four third fastener holes 242, the four second fastener holes 224, and the four first fastener holes 212 in sequence. In some embodiment, the heat dissipation base 210 has two first fastener holes 212 disposed diagonally to each other, the circuit board 220 has two second fastener holes 224 disposed diagonally to each other, and the mask cover 240 has two third fastener holes 242 disposed diagonally to each other, and the two first fasteners 260 pass through the two third fastener holes 242, the two second fastener holes 224, and the two first fastener holes 212 in sequence.

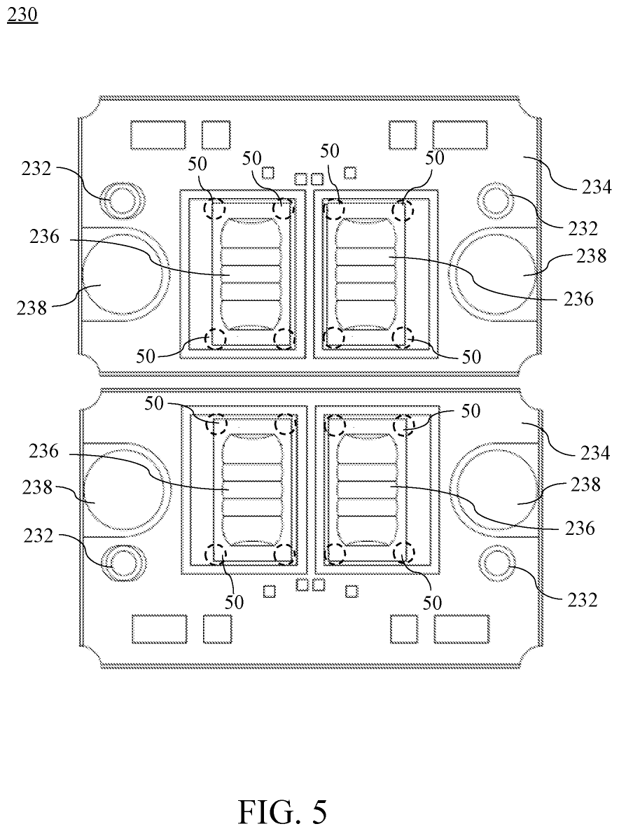

FIG. 5 is a diagram showing a top view of the light source unit of FIG. 2B. Referring to FIGS. 2B and 5, the heat dissipation base 210 has a plurality of alignment pins 218, and the light source unit 230 is provided with a plurality of alignment holes 232 corresponding to the plurality of alignment pins 218. When the light source unit 230 is disposed on the first surface 214 of the heat dissipation base 210, the plurality of alignment pins 218 of the heat dissipation base 210 are inserted into the plurality of alignment holes 232 of the light source unit 230 to position the light source unit 230. The circuit board 220 is further provided with a plurality of alignment holes 228 corresponding to another plurality of alignment pins 218 of the heat dissipation base 210, wherein when the circuit board 220 is disposed on the first surface 214 of the heat dissipation base 210, the another plurality of alignment pins 218 of the heat dissipation base 210 are inserted into the plurality of alignment holes 228 of the circuit board 220 to position the circuit board 220. For example, the heat dissipation base 210 has six alignment pins 218, the light source unit 230 is provided with four alignment holes 232, and the circuit board 220 is provided with two alignment holes 228.

Referring to FIGS. 2A, 2B, 4 and 5 together, the light source unit 230 comprises at least one light emitting element 234 and at least one lens assembly 236 corresponding thereto, there is glue 50 (as shown by the dotted circles) between the light emitting element 234 and the lens assembly 236 corresponding thereto. The light emitting element 234 comprises laser diode, LED diode, or a combination of the above. The light emitting element 234 may comprise the laser diode array(s). The light emitting element 234 is configured to emit color light, as the source of the illumination beam L. The glue 50 is, for example, disposed between the light emitting element 234 and the corners of the lens assembly 236 corresponding to the light emitting element 234.

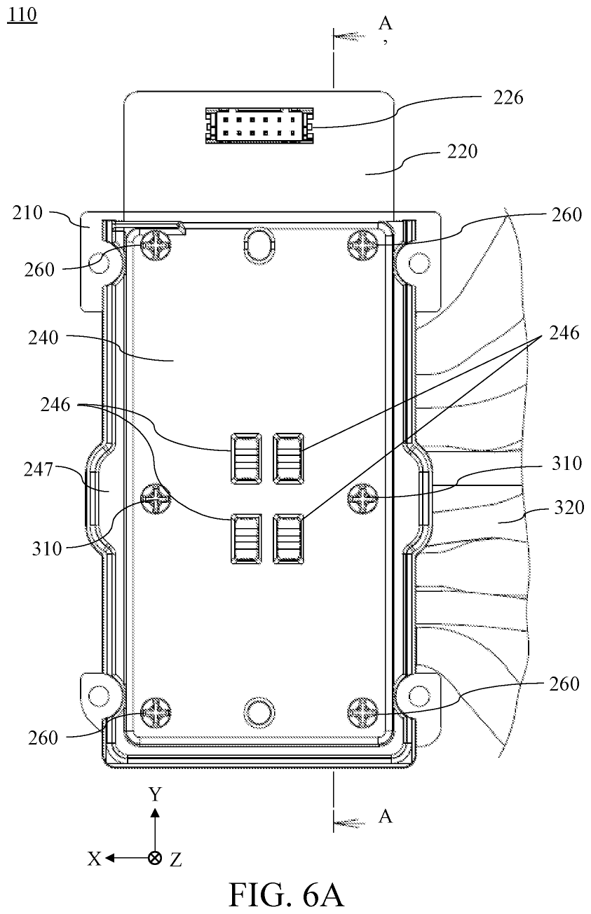

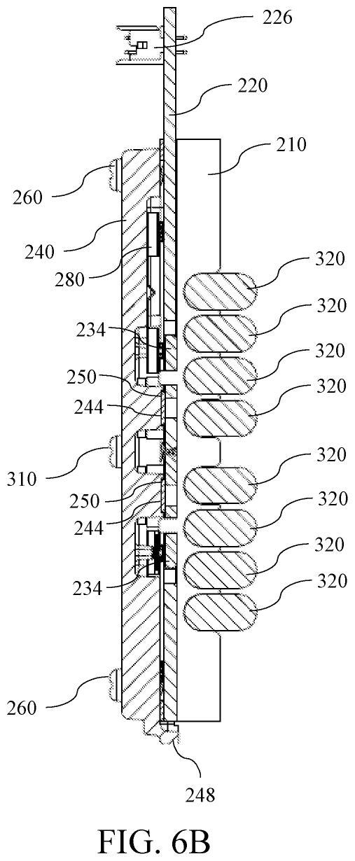

Referring to FIGS. 4, 5 and 6A together, FIG. 6A is a schematic diagram of the light source device of the projection device of FIG. 1 from a third viewing angle according to an embodiment of the disclosure. When the mask cover 240 is fastened on the heat dissipation base 210, the mask cover 240 covers an area with the glue 50 between the light emitting element 234 and the lens assembly 236 corresponding thereto, to block the ultraviolet light, which is generated when the light emitting element 234 operates and causes the aging of the glue 50. In this embodiment, the light source unit 230 comprises two light emitting element 234 and four lens assembly 236, each light emitting element 234 comprises two laser diode arrays, and each laser diode array corresponds to one of the four lens assembly 236 In an embodiment, the light source unit 230 further comprises a plurality of contact portions 238 disposed on the light emitting element 234 and around the laser diode arrays. The plurality of contact portions 238 correspond to the pressing members 250, and are configured to contact with the pressing members 250. The plurality of contact portions 238 may be holes or grooves.

FIG. 6B is a cross-sectional view along a line segment AA′ in FIG. 6A. Referring to FIGS. 6A and 6B together, one end of each pressing member 250 is connected to the mask cover 240, and another end of each pressing member 250 is configured to press against the light source unit 230 (the contact portions 238 of the light source unit 230); a number of the pressing members 250 is four, but the disclosure is not limited thereto. Since shape deformation due to manufacturing errors or the like may occur in the mask cover 240, it is considered that the mask cover 240 does not directly press the light source unit 230 to avoid crushing the light source unit 230. Therefore, the mask cover 240 presses the light source unit 230 on the heat dissipation base 210 through the plurality of pressing members 250, which are resilient members configured to absorb the deformation, wherein each of the resilient members is, for example, a spring, a rubber or an elastic piece.

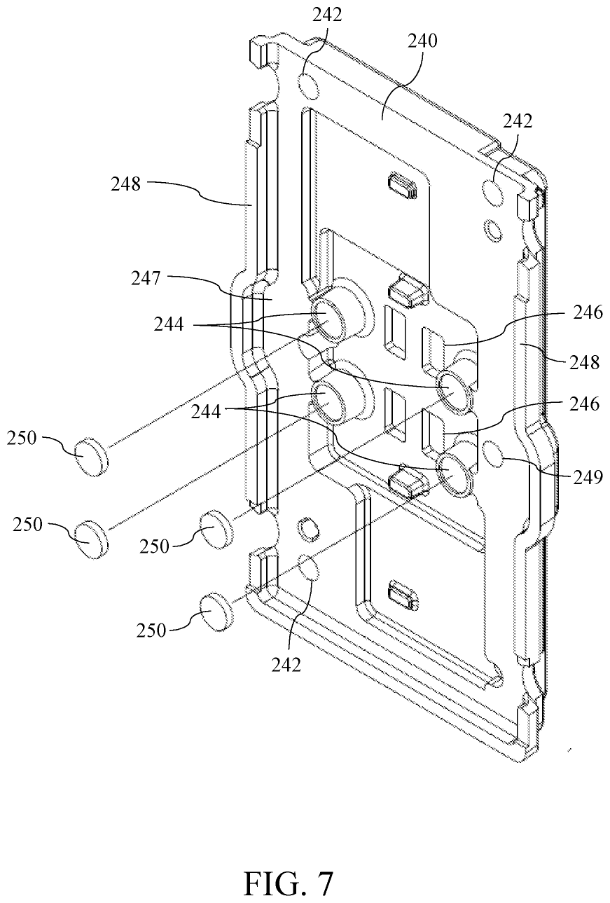

FIG. 7 is a schematic diagram of the mask cover and the pressing members of FIG. 3B. Referring to FIG. 7, the mask cover 240 is provided with a plurality of grooves 244, and the plurality of pressing members 250 are fixed in the plurality of grooves 244. Before the mask cover 240 is fastened on the heat dissipation base 210 through the first fasteners 260, the pressing members 250 are fixed on the mask cover 240. For example, the pressing members 250 are attached to in the grooves 244 by the adhesive.

Referring to FIGS. 2A, 6A and 7, the mask cover 240 is provided with an opening 246, and at least a part of the light source unit 230 is exposed from the opening 246. In other words, through the design of the opening 246, most of the light emitted by the light source unit 230 is not blocked by the mask cover 240. The mask cover 240 covers at least a part of the circuit board 220 to block the light, which is emitted by the light source unit 230 and output through the at least the part of circuit board 220 due to the refraction and reflection. A number of the opening(s) 246 corresponds to the number of the laser diode arrays.

To further block the light, which is emitted by the light source unit 230 and output through the circuit board 220 due to the refraction and reflection to avoid affecting projection quality, the mask cover 240 comprises an extension portion 248 extending from at least a part of an edge thereof toward the heat dissipation base 210, and the extension portion 248 of the mask cover 240 is configured to block at least a part of light emitted by the light source unit 230 as shown in FIGS. 2A, 3A and 7.

Referring to FIGS. 2B, 3B and 7, the mask cover 240 is, for example, made by die-casting for the above structure design such as the grooves 244, the opening 246 and the extension portion 248.

Referring to FIGS. 2B and 3B, the light source device 110 further comprises a sealing ring 280 disposed between the mask cover 240 and the circuit board 220 to block lateral light emitted from the light source unit 230, wherein the sealing ring 280 surrounds the sides of the light source unit 230.

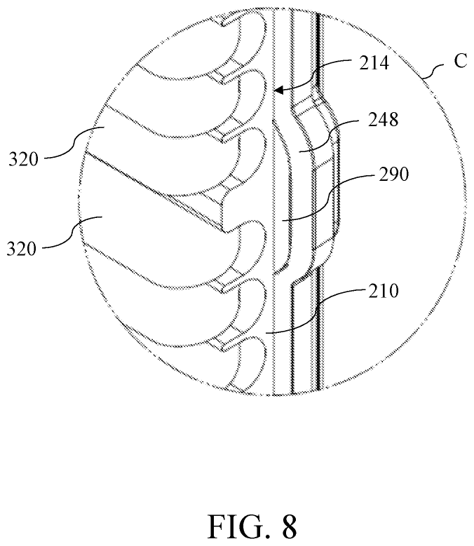

FIG. 8 is an enlarged schematic diagram of a region C in FIG. 3A. Referring to FIGS. 2B, 3A, 3B and 8, the light source device 110 further comprises an insulating sheet 290 disposed between the circuit board 220 and the heat dissipation base 210, wherein at least a part of a periphery edge of the insulating sheet 290 is connected to an inner edge of the extension portion 248 of the mask cover 240 to block the light emitted by the light source unit 230 and output through the circuit board 220 due to the refraction and reflection. The insulating sheet 290 is configured to block the light output through the surface of the circuit board 220 facing the first surface 214 of the heat dissipation base 210, and the extension portion 248 of the mask cover 240 is configured to block the light output through the side(s) of the circuit board 220. The insulating sheet 290 is, for example, a black polyester film such as polyethylene terephthalate (PET), or a black (dark color) mylar sheet. The insulating sheet 290 is further configured to isolate the circuit board 220 from the heat dissipation base 210. The insulating sheet 290 is provided with holes corresponding to the four second fastener holes 224 and is provided with a through hole corresponding to the through hole 222.

Referring to FIGS. 2A, 2B, 4, 6A and 7, the light source device 110 further comprises at least one second fastener 310, the heat dissipation base 210 has at least one fourth fastener hole 219, the mask cover 240 has at least one fifth fastener hole 249, and the through hole 222 of the circuit board 220 is provided with at least one notch 229, wherein the second fastener 310 passes through the fifth fastener hole 249, the notch 229, and the fourth fastener hole 219 in sequence. In this embodiment, long sides of the mask cover 240 have protrusions 247 corresponding to the notches 229, and long sides of the circuit board 220 have protrusions 227 corresponding to the notches 229.

Referring to FIGS. 3A and 3B, the light source device 110 further comprises a plurality of heat pipes 320, a number of heat pipes 320 is, for example, eight. The heat dissipation base 210 is disposed between the plurality of heat pipes 320 and the light source unit 230, and an extension section 322 of each of the plurality of heat pipes 320 is disposed on the heat dissipation base 210 and parallel to a short side of the heat dissipation base 210. The extension section 322 of each heat pipe 320 is disposed at a position which avoids the position of the fastener, such as the first fastener 260 and the second fastener 310, on the heat dissipation base 210, and near the light source unit 230. Thus, compared with the need to provide different fastener holes on the heat dissipation base 210 for fastening the circuit board and the light source unit, the design of the light source device 110 to reduce the number of first fastening holes 212 can make the heat dissipation base 210 have more areas on the second surface 216 for the disposition of the heat pipes 320, and the heat pipes 320 can be located near the light source unit 230, thereby improving the heat dissipation effect.

Besides, the light source device 110 further comprises a plurality of heat dissipation fins 330. The plurality of heat dissipation fins 330 are, for example, arranged along a direction and disposed in parallel. The section of each heat pipe 320 away from the extension section 322, for example, passes through these heat dissipation fins 330 along the direction.

Based on the above, the embodiments of the disclosure at least have one of the following advantages or effects. In the light source device or the projection device of the disclosure, the plurality of first fasteners fastens the mask cover and the circuit board on the heat dissipation base simultaneously, and the mask cover presses the light source unit on the heat dissipation base through the plurality of pressing members, wherein the first fastener holes may be close to the periphery of the heat dissipation base. Compared with the need to provide different fastener holes on the heat dissipation base for fastening the circuit board and the light source unit, the design of the light source device may effectively reduce the processing cost on the heat dissipation base, reduce the number of first fastener holes to reduce the use cost, and make the heat dissipation base have more areas on the second surface for the disposition of the heat pipes, and the heat pipes be located near the light source unit, thereby improving the heat dissipation effect. When the mask cover is fastened on the heat dissipation base, the mask cover may cover an area with the glue between the light emitting element and the lens assembly corresponding thereto, to block the ultraviolet light, which is generated when the light emitting element operates and causes the aging of the glue. The mask cover may comprise an extension portion extending from at least a part of an edge thereof toward the heat dissipation base to block at least a part of light emitted by the light source unit to avoid affecting projection quality. At least a part of a periphery edge of the insulating sheet disposed between the circuit board and the heat dissipation base may connect to an inner edge of the extension portion of the mask cover, wherein the insulating sheet is configured to block the light output through the surface of the circuit board facing the first surface of the heat dissipation base, and the extension portion of the mask cover is configured to block the light output through the side(s) of the circuit board, thereby avoiding affecting projection quality.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light source device, comprising:
a heat dissipation base with a plurality of first fastener holes;
a circuit board with a through hole and a plurality of second fastener holes disposed on the heat dissipation base;
a light source unit electrically connected to the circuit board, disposed on the heat dissipation base and located in the through hole;
a mask cover with a plurality of third fastener holes;
a plurality of pressing members fixed on the mask cover; and
a plurality of first fasteners passing through the plurality of third fastener holes, the plurality of second fastener holes, and the plurality of first fastener holes in sequence, the plurality of first fasteners is configured to fasten the mask cover and the circuit board on the heat dissipation base, and the mask cover is connected to the light source unit on the heat dissipation base through the plurality of pressing members.

2. The light source device according to claim 1, wherein the heat dissipation base has a plurality of alignment pins, and the light source unit is provided with a plurality of alignment holes corresponding to the plurality of alignment pins.

3. The light source device according to claim 1, wherein the plurality of pressing members are resilient members.

4. The light source device according to claim 3, wherein each of the resilient members is a spring, a rubber or an elastic piece.

5. The light source device according to claim 1, wherein the mask cover is provided with a plurality of grooves, and the plurality of pressing members are fixed in the plurality of grooves.

6. The light source device according to claim 1, wherein the mask cover is provided with an opening, and at least a part of the light source unit is exposed from the opening.

7. The light source device according to claim 1, wherein the mask cover covers at least a part of the circuit board.

8. The light source device according to claim 1, wherein the light source unit comprises a light emitting element and a lens assembly, there is glue between the light emitting element and the lens assembly, and the mask cover covers an area with the glue between the light emitting element and the lens assembly.

9. The light source device according to claim 1, wherein the mask cover comprises an extension portion extending from at least a part of an edge thereof toward the heat dissipation base, and the extension portion is configured to block at least a part of light emitted by the light source unit.

10. The light source device according to claim 9, further comprising an insulating sheet disposed between the circuit board and the heat dissipation base, wherein at least a part of a periphery edge of the insulating sheet is connected to an inner edge of the extension portion.

11. The light source device according to claim 1, further comprising a sealing ring disposed between the mask cover and the circuit board to block lateral light emitted from the light source unit.

12. The light source device according to claim 1, wherein the mask cover is made by die-casting.

13. The light source device according to claim 1, further comprising a plurality of heat pipes, wherein the heat dissipation base is disposed between the plurality of heat pipes and the light source unit, and an extension portion of each of the plurality of heat pipes is disposed on the heat dissipation base and parallel to a short side of the heat dissipation base.

14. The light source device according to claim 1, further comprising a second fastener, the heat dissipation base having a fourth fastener hole, the mask cover having a fifth fastener hole, the through hole being provided with a notch, wherein the second fastener passes through the fifth fastener hole, the notch, and the fourth fastener hole in sequence, and long sides of the mask cover and the circuit board have protrusions corresponding to the notch.

15. A projection device, comprising:
a light source device, comprising:
a heat dissipation base with a plurality of first fastener holes;
a circuit board with a through hole and a plurality of second fastener holes disposed on the heat dissipation base;
a light source unit electrically connected to the circuit board, disposed on the heat dissipation base and located in the through hole;
a mask cover with a plurality of third fastener holes;
a plurality of pressing members fixed on the mask cover; and
a plurality of fasteners passing through the plurality of third fastener holes, the plurality of second fastener holes, and the plurality of first fastener holes in sequence, the plurality of fasteners is configured to fasten the mask cover and the circuit board on the heat dissipation base, and the mask cover is connected to the light source unit on the heat dissipation base through the plurality of pressing members;
a light valve disposed on a transmission path of an illumination beam generated by the light source device and configured to convert the illumination beam into an image beam; and
a projection lens disposed on a transmission path of the image beam and configured to project the image beam.

16. The projection device according to claim 15, wherein the mask cover is provided with an opening, and at least a part of the light source unit is exposed from the opening.

17. The projection device according to claim 15, wherein the mask cover covers at least a part of the circuit board.

18. The projection device according to claim 15, wherein the light source unit comprises a light emitting element and a lens assembly, there is glue between the light emitting element and the lens assembly, and the mask cover covers an area with the glue between the light emitting element and the lens assembly.

19. The projection device according to claim 15, wherein the mask cover comprises an extension portion extending from at least a part of an edge thereof toward the heat dissipation base, and the extension portion is configured to block at least a part of light emitted by the light source unit.

20. The projection device according to claim 19, wherein the light source device further comprises an insulating sheet disposed between the circuit board and the heat dissipation base, and at least a part of a periphery edge of the insulating sheet is connected to an inner edge of the extension portion.
